(19) United States
(12) Patent Application Publication
(10) Pub. No.: US 2025/0357122 A1
(43) Pub. Date: Nov. 20, 2025

(54) METHOD OF MANUFACTURING A SEMICONDUCTOR DEVICE INCLUDING AN OHMIC CONTACT AND A GATE DIELECTRIC

(71) Applicant: Infineon Technologies AG, Neubiberg (DE)

(72) Inventors: Armin TILKE, Dresden (DE); Alexey MIKHAYLOV, Villach (AT); Fabian RASINGER, Villach (AT); Wolfgang LEHNERT, Freudenberg GT Lintach (DE); Gerald RESCHER, Maria Saal (AT); Francisco Javier SANTOS RODRIGUEZ, St.Jakob im Rosental (AT); Carsten SCHAEFFER, Annenheim (AT)

(21) Appl. No.: 19/206,961

(22) Filed: May 13, 2025

(30) Foreign Application Priority Data
May 14, 2024 (DE) 102024113455.0

(51) Int. Cl. H01L 21/04; H01L 21/308; H10D 30/01; H10D 30/62; H10D 62/832

(52) U.S. Cl. CPC H01L 21/0485; H01L 21/049; H01L 21/308; H10D 30/024; H10D 30/62; H10D 62/8325

(57) ABSTRACT

A method of manufacturing a semiconductor device is proposed. The method includes forming doped regions in a SiC semiconductor body at a first surface of the SiC semiconductor body. The method further includes forming an ohmic contact to at least part of the doped regions on the first surface of the SiC semiconductor body. Thereafter a gate dielectric is formed on the SiC semiconductor body.

### RELATED APPLICATION

This application claims priority to German Patent Application No. 102024113455.0, filed on May 14, 2024, entitled “METHOD OF MANUFATURING A SEMICONDUCTOR DEVICE INCLUDING AN OHMIC CONTACT AND A GATE DIELECTRIC”, which is incorporated by reference herein in its entirety.

### TECHNICAL FIELD

The present disclosure is related to a method of manufacturing a semiconductor device, in particular to method of manufacturing a semiconductor device including an ohmic contact and a gate dielectric.

### BACKGROUND

Technology development of new generations of wide bandgap semiconductor devices such as silicon carbide (SiC) semiconductor devices, e.g. insulated gate field effect transistors (IGFETs) such as metal oxide semiconductor field effect transistors (MOSFETs) or insulated gate bipolar transistors (IGBTs), aims at improving electrical device characteristics and reducing costs by shrinking device geometries. Although costs may be reduced by shrinking device geometries, a variety of tradeoffs and challenges have to be met when increasing device functionalities per unit area. For example, reducing the area-specific on-state resistance, RₒₙxA, while maintaining device reliability may be challenging in view of process-related restrictions when applying a thermal budget to a semiconductor substrate during device processing. Such process-related restrictions may be caused by, for example, restrictions of structural elements with respect to thermal budget. For example, thermal budget restrictions may apply to ohmic contacts and/or gate dielectrics for avoiding damage to these structural elements.

There is a need for improving a method of manufacturing a semiconductor device.

### SUMMARY

An example of the present disclosure relates to a method of manufacturing a semiconductor device. The method includes forming doped regions in a SiC semiconductor body at a first surface of the SiC semiconductor body. The method further includes forming an ohmic contact to at least part of the doped regions on the first surface of the SiC semiconductor body. Thereafter, the method includes forming a gate dielectric on the SiC semiconductor body.

Another example of the present disclosure relates to a further method of manufacturing a semiconductor device. The method includes forming doped regions in a SiC semiconductor body at a first surface of the SiC semiconductor body. The method includes forming a gate trench into the SiC semiconductor body at the first surface. The method further includes forming a gate dielectric in the gate trench and filling the gate trench with an auxiliary material. The method further includes forming an ohmic contact to at least part of the doped regions on the first surface of the SiC semiconductor body. Thereafter, the method includes removing the auxiliary material from the gate trench and forming a metal layer structure. A first part of the metal layer structure is formed on the gate dielectric and constitutes a gate electrode. A second part of the metal layer structure is formed on the ohmic contact.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the embodiments and are incorporated in and constitute a part of this specification. The drawings illustrate embodiments of semiconductor devices and methods of manufacturing semiconductor devices and together with the description serve to explain principles of the embodiments. Further embodiments are described in the following detailed description and the claims.

FIG. 1 is an exemplary process illustration of manufacturing a semiconductor device.

FIGS. 2A to 2F, 3A to 3D, 4A to 4C, 5A to 5F, 6A to 6F, 7A to 7F, 8A to 8M, 9A to 9C are schematic cross-sectional views for illustrating process features of exemplary methods of manufacturing a semiconductor device based on the process of FIG. 1.

FIG. 10 refers to a further exemplary process illustration of manufacturing a semiconductor device.

FIGS. 11A to 11l are schematic cross-sectional views for illustrating process features of an exemplary method of manufacturing a semiconductor device based on the process of FIG. 10.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact is a non-rectifying electrical junction.

If two elements A and B are combined using an “or”, this is to be understood to disclose all possible combinations, i.e. only A, only B as well as A and B, if not explicitly or implicitly defined otherwise. An alternative wording for the same combinations is “at least one of A and B” or “A and/or B”. The same applies, mutatis mutandis, for combinations of more than two elements.

Ranges given for physical dimensions include the boundary values. For example, a range for a parameter y from a to b reads as a≤y≤b. The same holds for ranges with one boundary value like “at most” and “at least”.

Main constituents of a layer or a structure from a chemical compound or alloy are such elements which atoms form the chemical compound or alloy. For example, silicon (Si) and carbon (C) are the main constituents of a silicon carbide (SiC) layer.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

The description and drawings merely illustrate the principles of the disclosure. Furthermore, all examples recited herein are principally intended expressly to be only for illustrative purpose to aid the reader in understanding the principles of the disclosure and the concepts contributed to furthering the art. All statements herein reciting principles, aspects, and examples of the disclosure, as well as specific examples thereof, are intended to encompass equivalents thereof.

Some of the below examples are described in connection with a silicon carbide substrate. Alternatively, another wide band gap semiconductor substrate, e.g. a wide band gap wafer, may be processed, e.g. comprising a wide band gap semiconductor material different from silicon carbide. The wide band gap semiconductor wafer may have a band gap larger than the band gap of silicon (1.12 eV). For example, the wide band gap semiconductor wafer may be a gallium arsenide (GaAs) wafer. In some examples, the semiconductor body may be based on a silicon substrate.

In some of the illustrated examples, n-channel MOSFETs or IGBTs are illustrated. However, the examples described herein may also be applied to p-channel devices, e.g. p-channel MOSFETs or IGBTs.

The description and drawings merely illustrate the principles of the disclosure. Furthermore, all examples recited herein are principally intended expressly to be only for illustrative purpose to aid the reader in understanding the principles of the disclosure and the concepts contributed to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

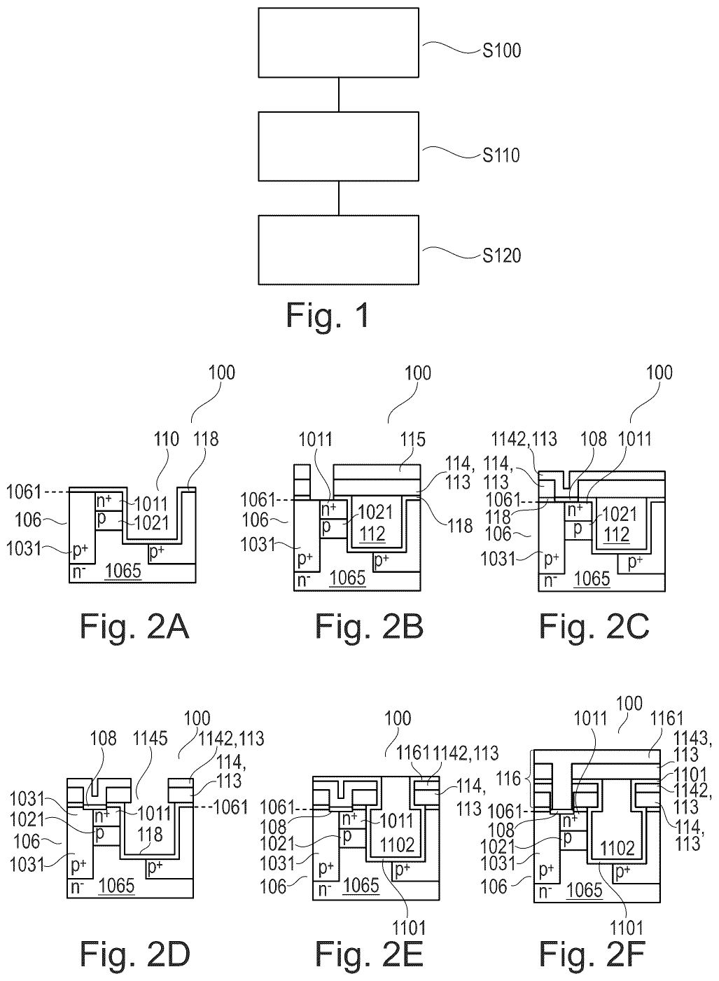

An example of a method of manufacturing a semiconductor device is illustrated by referring to the flowchart of FIG. 1.

Process feature S100 includes forming doped regions in a SiC semiconductor body at a first surface of the SiC semiconductor body.

Process feature S110 includes forming an ohmic contact to at least part of the doped regions on the first surface of the SiC semiconductor body.

After carrying out process features S100 and S110, process feature S120 includes forming a gate dielectric on the SiC semiconductor body.

The semiconductor device may be part of an integrated circuit or may be a discrete semiconductor device or a semiconductor module, for example. The semiconductor device may be or may include an insulated gate field effect transistor (IGFET) such as a metal oxide semiconductor field effect transistor (MOSFET) or an insulated gate bipolar transistor (IGBT), for example. The semiconductor device may be a vertical semiconductor device having a load current flow between the first surface and a second surface opposite to the first surface along a vertical direction. The vertical power semiconductor device may be configured to conduct currents of more than 1A, or more than 10 A, or more than 30 A, or more than 50 A, or more than 75 A, or even more than 100 A, and may be further configured to block voltages between load electrodes, e.g. between collector and emitter on an IGBT, or between drain and source of a MOSFET, in the range of several hundreds of up to several thousands of volts, e.g. 400 V, 650 V, 1.2 kV, 1.7 kV, 3.3 kV, 4.5 kV, 5.5 kV, 6 kV, 6.5 kV, 10 kV. The blocking voltage may correspond to a voltage class specified in a datasheet of the power semiconductor device, for example.

The semiconductor device may be based on a SiC semiconductor body from a crystalline SiC material. The crystalline SiC material may have a hexagonal crystal lattice, by way of example. For example, the semiconductor material may be 2H—SiC (SiC of the 2H polytype), 6H—SiC or 15R—SiC. According to an example, the semiconductor material is silicon carbide of the 4H polytype (4H—SiC). The SiC semiconductor body may include or consist of a semiconductor substrate having none, one or more than one semiconductor layers, e.g. epitaxially grown layers, thereon. One of the semiconductor layers may be a doped semiconductor layer of a current spread layer, for example.

The first surface may define a front surface or a top surface of the SiC semiconductor body, and the SiC semiconductor body may further have a second surface that may be a back surface or a rear surface of the SiC semiconductor body, for example. The SiC semiconductor body may be attached to a lead frame via the second surface, for example. Over the first surface of the SiC semiconductor body, bond pads may be arranged and bond wires may be bonded on the bond pads, for example.

For realizing a desired current carrying capacity, the SiC semiconductor device may be designed by a plurality of parallel-connected SiC semiconductor device cells. The parallel-connected SiC semiconductor device cells may, for example, be SiC semiconductor device cells formed in the shape of a strip or a strip segment. Of course, the SiC semiconductor device cells can also have any other shape, e.g. circular, elliptical, polygonal such as hexagonal or octahedral. The semiconductor device cells may be arranged in a transistor cell area of the SiC semiconductor body. The transistor cell area may be an area where an emitter region of an IGBT (or a source region of a MOSFET) and a collector region of an IGBT (or a drain region of a MOSFET) are arranged opposite to one another along a vertical direction. In the transistor cell area, a load current may enter or exit the SiC semiconductor body of the semiconductor device, e.g. via contact plugs or contact lines on the top surface of the mesa. The semiconductor device may further include an edge termination area that may include a termination structure. In a blocking mode or in a reverse biased mode of the semiconductor device, the blocking voltage between the transistor cell area and a field-free region laterally drops across the termination structure. The termination structure may have a higher or a slightly lower voltage blocking capability than the transistor cell area. The termination structure may include a junction termination extension (JTE) with or without a variation of lateral doping (VLD), one or more laterally separated guard rings, or any combination thereof, for example.

Forming the doped regions may include at least one masked or unmasked, e.g. unmasked with respect to a transistor cell area, ion implantation process. The ion implantation process may be based on an ion implantation mask patterned by photolithography, for example. The ion implantation mask may be a hard mask, for example. Forming the doped regions may include introducing n- and/or p-type dopants into the SiC semiconductor body. For example, dopants in a semiconductor body comprising SiC may include AI, B, Be, Ga, or any combination thereof for p-type doping, and N, P, or any combination thereof for n-type doping.

Forming the ohmic contact may include processing temperatures exceeding 850° C., for example. Forming the ohmic contact may include a silicidation process, e.g. a Ni-based silicidation process, e.g. NiSi, involving processing temperatures of 900° C. or higher.

By forming the ohmic contact on the doped regions prior to formation of the gate dielectric, the ohmic contact formation no longer poses a temperature restriction on the selection of gate dielectric materials. Gate dielectric materials may degrade when the ohmic contact is formed after gate dielectric at temperatures exceeding the crystallization temperature of the gate dielectric, for example. High-k dielectric materials, e.g. Al₂O₃, ZrO₂, HfO₂, AlN, aluminosilicate AlSiOₓ, silicon doped HfO₂, lanthanum doped HfO₂, TiO₂, Y₂O₃ or Si₃N₄, ONO (oxide-nitride-oxide), or any stacked combination thereof, may be used. In view of the processing sequence described in the examples herein, dielectric materials such as HfO₂ and/or ZrO₂ having crystallization temperatures in the 600° C. to 800° C. range can be used. This allows for improving a method of manufacturing a semiconductor device.

For example, forming the ohmic contact may include processing the SiC semiconductor body at temperatures higher than a crystallization temperature of the gate dielectric. For example, forming the ohmic contact may exceed temperatures of 900° C. for forming a Ni-based silicide.

For example, the method may include, before forming the ohmic contact, forming a gate trench into the SiC semiconductor body at the first surface.

For example, forming the doped regions may include forming a source or emitter layer of a first conductivity type. Forming the doped regions may include and forming a body layer of a second conductivity type. The method may further include patterning the source layer to source regions and patterning the body layer to body regions by etching through the source layer and etching through the body layer when forming the gate trench. The source regions and the body regions may constitute at least part of the doped regions.

For example, the method may further include filling the gate trench with an auxiliary material before forming the ohmic contact. The method may further include removing the auxiliary material from the gate trench after forming the ohmic contact and before forming the gate dielectric. For example, the auxiliary material may be chosen with respect to etch selectivity to an underlying material in the gate trench on which it is formed. This allows the underlying material to act as an etch stop when removing the auxiliary material. For example, the auxiliary material may be polycrystalline silicon, or silicon nitride, or an oxide of silicon.

For example, the method may further include, before removing the auxiliary material, forming an intermediate dielectric layer over the auxiliary material and the first surface of the SiC semiconductor body. The method may further include exposing a top surface portion of the auxiliary material by forming an opening in the intermediate dielectric layer. The intermediate dielectric layer may remain as part of a wiring area over the first surface of the SiC semiconductor body, e.g. as an insulating layer between the SiC semiconductor body and a lowermost wiring level of the wiring area, or may or may be replaced by another intermediate dielectric layer. The intermediate dielectric may also prevent diffusion and contamination from entering the SiC semiconductor body and may further cover the ohmic contact for protecting the ohmic contact from damage caused by processes applied to the SiC semiconductor body, e.g. atomic layer deposition, ALD chemistry, for example. Exemplary materials for the intermediate dielectric layer are SiO₂ or SiN, but any other materials suitable for the above purpose(s) may be used.

For example, the method may further include forming a metal layer structure. A first part of the metal layer structure may be formed on the gate dielectric and may constitute a gate electrode. A second part of the metal layer structure may be formed on the ohmic contact. For example, the metal layer structure may be or may include a Ti, TiN or Ti/TIN layer.

For example, the method may further include, before forming the gate dielectric, forming an intermediate dielectric layer on the first surface of the SiC semiconductor body. The method may further include exposing a gate portion of the SiC semiconductor body at the first surface of the SiC semiconductor body. Exposing the gate portion of the SiC semiconductor body at the first surface may include forming an opening in the intermediate dielectric layer. Thereafter, the method may further include forming the gate dielectric on the exposed gate portion of the SiC semiconductor body at the first surface of the SiC semiconductor body. The intermediate dielectric layer may remain as part of a wiring area over the first surface of the SiC semiconductor body or may be replaced by another intermediate dielectric layer. The gate dielectric on the exposed gate portion may define a planar MOSFET or IGBT, for example.

For example, the method may further include, after forming the intermediate dielectric layer and before exposing the gate portion, exposing a contact portion of the SiC semiconductor body at the first surface of the SiC semiconductor body. Exposing the contact portion of the SiC semiconductor body at the first surface may include forming an opening in the intermediate dielectric layer. Thereafter, the method may further include forming the ohmic contact on the exposed contact portion of the SiC semiconductor body at the first surface of the SiC semiconductor body.

For example, the method may further include forming a metal layer structure. A first part of the metal layer structure may be formed on the gate dielectric, e.g. on a planar gate dielectric. The first part of the metal layer structure may constitute a gate electrode. A second part of the metal layer structure may be formed on the ohmic contact. For example, the metal layer structure may be or may include a Ti, TiN or Ti/TiN layer.

For example, the method may further include, after forming the ohmic contact, forming a gate trench into the SiC semiconductor body at the first surface.

For example, the method may further include forming a source or emitter layer of a first conductivity type. The method may further include forming a body layer of a second conductivity type. The method may further include patterning the source layer to source regions and patterning the body layer to body regions by etching through the source layer and etching through the body layer when forming the gate trench. The source regions and the body regions may constitute at least part of the doped regions.

For example, the method may further include, before forming the gate trench, forming an intermediate dielectric layer on the first surface of the SiC semiconductor body. The method may further include exposing a gate portion of the SiC semiconductor body at the first surface of the SiC semiconductor body. Exposing the gate portion of the SiC semiconductor body at the first surface may include forming an opening in the intermediate dielectric layer. Thereafter, the method may further include forming the gate trench into the SiC semiconductor body at the first surface. The intermediate dielectric layer may remain as part of a wiring area over the first surface of the SiC semiconductor body or may be replaced by another intermediate dielectric layer. The gate dielectric on the exposed gate portion may define a planar MOSFET or IGBT, for example.

For example, the intermediate dielectric layer may be formed before forming the ohmic contact. The method may further include exposing a contact portion of the SiC semiconductor body at the first surface of the SiC semiconductor body. Exposing the contact portion of the SiC semiconductor body at the first surface may include forming an opening in the intermediate dielectric layer. Thereafter, the method may further include forming the ohmic contact on the exposed contact portion of the SiC semiconductor body at the first surface of the SiC semiconductor body.

For example, the method may further include forming the doped regions including forming a source layer of a first conductivity type. Forming the doped regions may further include forming a body layer of a second conductivity type. Forming the doped regions may further include patterning the source layer to source regions and patterning the body layer to body regions by etching through the source layer and etching through the body layer when forming gate trenches. The source regions and the body regions may constitute at least part of the doped regions. The method may further include filling the gate trenches with an auxiliary material before forming the ohmic contact. The method may further include removing the auxiliary material from the gate trenches after forming the ohmic contact and before forming the gate dielectric. For example, the auxiliary material may be chosen with respect to etch selectivity to an underlying material in the gate trench on which it is formed. This allows the underlying material to act as an etch stop when removing the auxiliary material. For example, the auxiliary material may be polycrystalline silicon, or silicon nitride, or an oxide of silicon.

For example, the method may include, before forming the ohmic contact, forming an intermediate dielectric layer over the auxiliary material and the first surface of the SiC semiconductor body. The method may further include exposing a contact portion of the SiC semiconductor body at the first surface of the SiC semiconductor body. Exposing the contact portion of the SiC semiconductor body at the first surface may include forming an opening in the intermediate dielectric layer. Thereafter, the method may further include forming the ohmic contact on the exposed contact portion of the SiC semiconductor body at the first surface of the SiC semiconductor body.

For example, the method may include, before removing the auxiliary material, exposing a top surface portion of the auxiliary material by forming an opening in the intermediate dielectric layer. The intermediate dielectric layer or part thereof may remain as part of a wiring area over the first surface of the SiC semiconductor body. Thereafter, the method may further include forming the gate dielectric. For example, the semiconductor device may be a fin field effect transistor (FinFET).

For example, forming the gate dielectric may include forming a high-k dielectric. For example, the high-k dielectric material may include Al₂O₃, ZrO₂, HfO₂, AlN, aluminosilicate AlSiOₓ, silicon doped HfO₂, lanthanum doped HfO₂, TiO₂, Y₂O₃ or Si₃N₄, ONO (oxide-nitride-oxide), mixtures thereof, or any stacked combination thereof. The high-k dielectric may be formed by any suitable layer formation technique, e.g. atomic layer deposition (ALD) and/or chemical vapor deposition. Selection of the layer formation technique may depend on the layer formation temperature required for the respective layer formation technique, for example.

Details with respect to structure, or function, or technical benefit of features described above with respect to a semiconductor device such as a FET, or IGBT likewise apply to the exemplary methods described further below. Processing the SiC semiconductor body may comprise one or more optional additional features corresponding to one or more aspects mentioned in connection with the proposed concept or one or more examples described above or below.

The process features may include sub-processes. For example, some or all sub-processes of a process feature described herein may be carried out before or after of between sub-processes of another process feature described herein.

Referring to the schematic cross-sectional views FIGS. 2A to 2F are for illustrating process features of an exemplary method of manufacturing a semiconductor device 100. The semiconductor device is exemplified as a trench MOSFET.

Referring to the schematic cross-sectional view of FIG. 2A, doped regions are formed in a SiC semiconductor body 106 including an n⁻-doped drift region 1065. The doped regions include an n⁺-doped source region 1011, a p-doped body region 1021 and a p-doped auxiliary region 1031. A gate trench 110 is formed in the SiC semiconductor body 106 at a first surface 1061 of the SiC semiconductor body 106. A sacrificial layer 118, e.g. a sacrificial oxide layer, is formed on the first surface 1061 of the SiC semiconductor body 106 and on sidewalls and a bottom side of the gate trench 110. The gate trench 110 and the sacrificial layer 118 may be formed before, or after, or between processes for forming the doped regions.

Referring to the schematic cross-sectional view of FIG. 2B, the gate trench 110 is filled with an auxiliary material 112. An intermediate dielectric layer 114 as part of an intermediate dielectric structure 113 is formed on the surface 1061 of the SiC semiconductor body 106 and patterned by a mask 115, e.g. a resist mask, for defining a contact opening to the first surface 1061 of the SiC semiconductor body 106.

Referring to the schematic cross-sectional view of FIG. 2C, an ohmic contact 108 is formed on the portion of the first surface 1061 of the SiC semiconductor body that is exposed by the contact opening, e.g. by silicidation process. The ohmic contact 108 is covered by a protective intermediate dielectric layer 1142 as part of the intermediate dielectric structure 113. The protective intermediate dielectric layer 1142 may prevent diffusion and contamination and may protect the ohmic contact, e.g. from ALD chemistry. Optionally, a rapid thermal processing, RTP, may be carried out.

Referring to the schematic cross-sectional view of FIG. 2D, a top surface portion of the auxiliary material is exposed by forming an opening 1145 in the intermediate dielectric structure 113. The auxiliary material 112 is removed from the gate trench 110, e.g. by an etch process.

Referring to the schematic cross-sectional view of FIG. 2E, the sacrificial layer 118 is removed from the gate trench 110, e.g. by an etch process. A gate dielectric 1101 is formed at least on the bottom side and the sidewalls of the gate trench 110, e.g. by high-k layer deposition technique(s). A gate electrode 1102 is formed on the gate dielectric 1101 and recessed up to a top side of the intermediate dielectric structure 113 or up to a top side of the gate dielectric 1101 deposited on the intermediate dielectric structure 113.

Referring to the schematic cross-sectional view of FIG. 2F, a second intermediate dielectric layer 1143 as part of the dielectric structure 113 is formed over the SiC semiconductor body 106. A contact opening is formed, e.g. by a masked etched process, in the intermediate dielectric structure 113 for exposing the ohmic contact 108. The contact opening is filled with a contact plug extending into a first wiring level 1161, e.g. a metal layer closest to the first surface 1061, of a wiring area 116 over the SiC semiconductor body 106.

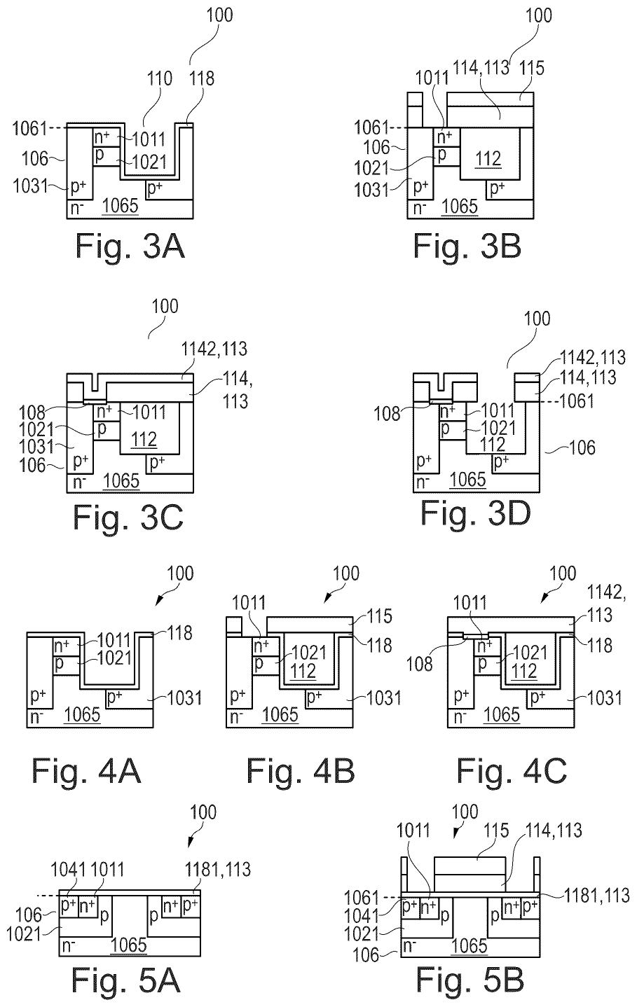

Referring to the schematic cross-sectional views FIGS. 3A to 3D, process features of a further exemplary method of manufacturing a semiconductor device 100 are illustrated. The process features of FIGS. 3A to 3D exemplify a modification of the process features illustrated in FIG. 2A to 2F.

The process feature illustrated in FIG. 3A is similar to the process feature illustrated in FIG. 2A. Referring to FIG. 3B, the sacrificial layer 118 is removed from the gate trench 110 before filling the gate trench 110 with the auxiliary material 112. Formation of the ohmic contact 108 and removal of the auxiliary material 112 from the gate trench 110 illustrated in FIGS. 3B to 3D are similar to the process features described with reference to FIGS. 2B to 2D. Formation of the gate dielectric 1101, the gate electrode 1102, the second intermediate dielectric layer 1143 and the first wiring level 1161 can follow as described with reference to FIGS. 2E and 2F above.

Referring to the schematic cross-sectional views FIGS. 4A to 4C, process features of a further exemplary method of manufacturing a semiconductor device 100 are illustrated. The process features of FIGS. 4A to 4C exemplify a modification of the process features illustrated in FIG. 2A to 2F.

The process feature illustrated in FIG. 4A is similar to the process feature illustrated in FIG. 2A. Referring to FIG. 4B, formation of the intermediate dielectric layer 114 illustrated in FIG. 2B is omitted and the mask 115 for defining the contact opening for the ohmic contact 108 is formed on the SiC semiconductor body 106 after filling the gate trench 110 with the auxiliary material 112. After forming the ohmic contact 108 and removing the mask 115, the protective intermediate dielectric layer 1142 is formed as illustrated in FIG. 4C. Process features as described with reference to FIGS. 2D to 2F can follow.

Similar to the process features described with reference to FIGS. 3A to 3D, removal of the sacrificial layer 118 from the gate trench 110 before filling the gate trench 110 with the auxiliary material 112 may also be applied to the exemplary process features of FIGS. 4A to 4C.

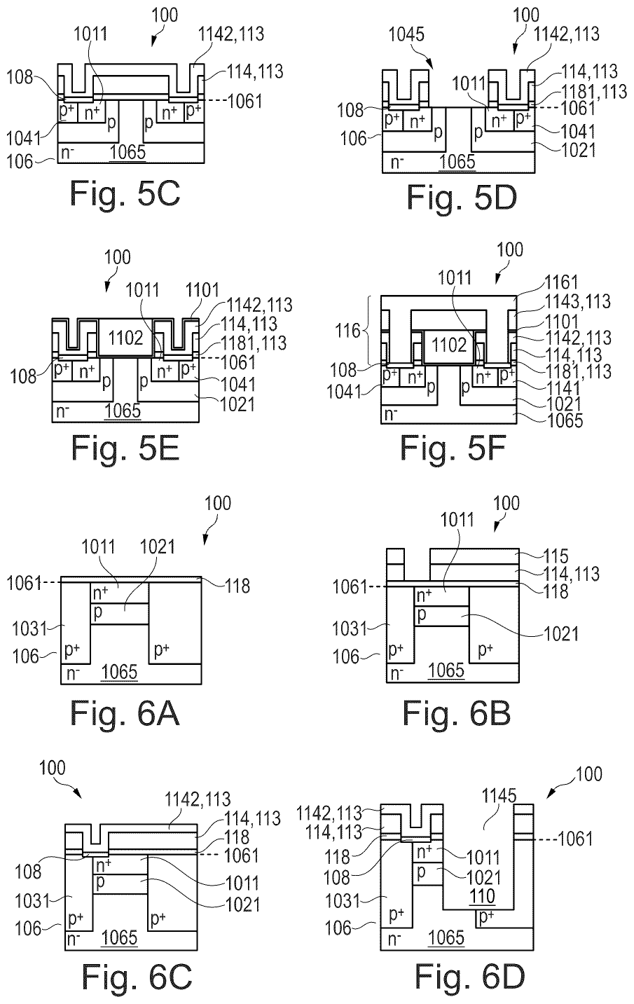

The schematic cross-sectional views FIGS. 5A to 5F are for illustrating process features of an exemplary method of manufacturing a semiconductor device 100. The semiconductor device is exemplified as a planar MOSFET.

Referring to the schematic cross-sectional view of FIG. 5A, doped regions are formed in the SiC semiconductor body 106 including an n⁻-doped drift region 1065. The doped regions include an n⁺-doped source region 1011, a p-doped body region 1021 and a p⁺-doped body contact region 1041. Similar to the sacrificial layer 118 illustrated in FIG. 2A, a cover dielectric 1181 as part of the intermediate dielectric structure 113 is formed on the first surface 1061 of the SiC semiconductor body 106.

Referring to the schematic cross-sectional view of FIG. 5B, an intermediate dielectric layer 114 as part of an intermediate dielectric structure 113 is formed over the surface 1061 of the SiC semiconductor body 106 and patterned by a mask 115, e.g. resist mask, for defining a contact opening to the first surface 1061 of the SiC semiconductor body 106.

Referring to the schematic cross-sectional view of FIG. 5C, an ohmic contact 108 is formed on the portion of the first surface 1061 of the SiC semiconductor body that is exposed by the contact opening, e.g. by a silicidation process. The ohmic contact 108 is covered by a protective intermediate dielectric layer 1142 as part of the intermediate dielectric structure 113. The protective intermediate dielectric layer 1142 may prevent diffusion and contamination and may protect the ohmic contact, e.g. from ALD chemistry.

Referring to the schematic cross-sectional view of FIG. 5D, a planar gate portion on the first surface 1061 is exposed by forming an opening 1145 in the intermediate dielectric structure 113, e.g. by an etch process.

Referring to the schematic cross-sectional view of FIG. 5E, a gate dielectric 1101 is formed at least on the exposed planar gate portion at the first surface 1061, e.g. by high-k layer deposition technique(s). A gate electrode 1102 is formed on the gate dielectric 1101 and recessed up to a top side of the intermediate dielectric structure 113 or up to a top side of the gate dielectric layer 1101 deposited on the intermediate dielectric structure 113. A second intermediate dielectric layer 1143 as part of the dielectric structure 113 is formed over the protective intermediate dielectric layer 1142.

Referring to the schematic cross-sectional view of FIG. 5F, a contact opening is formed, e.g. by a masked etched process, in the intermediate dielectric structure 113 for exposing the ohmic contact 108. The contact opening is filled with a contact plug extending into a first wiring level 1161, e.g. a metal layer closest to the first surface 1061, of a wiring area 116 over the SiC semiconductor body 106.

Similar to the process features described with reference to FIGS. 4A to 4C, omission of the intermediate dielectric layer 114 may also be applied to the exemplary process features of FIGS. 5A to 5F.

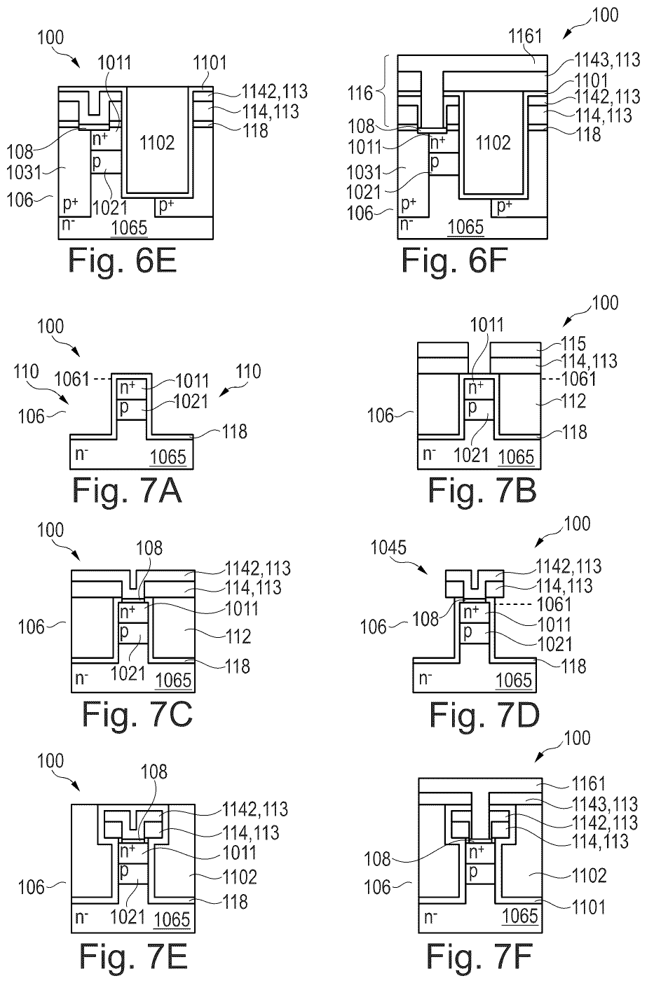

The schematic cross-sectional views FIGS. 6A to 6F are for illustrating process features of an exemplary method of manufacturing a semiconductor device 100. The semiconductor device is exemplified as a trench MOSFET.

Referring to the schematic cross-sectional view of FIG. 6A, doped regions are formed in the SiC semiconductor body 106 including an n⁻-doped drift region 1065. The doped regions include an n⁺-doped source region 1011, a p-doped body region 1021 and a p-doped auxiliary region 1031. A sacrificial layer 118, e.g. a sacrificial oxide layer, is formed on the first surface 1061 of the SiC semiconductor body 106.

Referring to the schematic cross-sectional view of FIG. 6B, an intermediate dielectric layer 114 as part of an intermediate dielectric structure 113 is formed on the surface 1061 of the SiC semiconductor body 106 and patterned by a mask 115, e.g. resist mask, for defining a contact opening to the first surface 1061 of the SiC semiconductor body 106.

Referring to the schematic cross-sectional view of FIG. 6C, an ohmic contact 108 is formed on the portion of the first surface 1061 of the SiC semiconductor body that is exposed by the contact opening, e.g. by a silicidation process. The ohmic contact 108 is covered by a protective intermediate dielectric layer 1142 as part of the intermediate dielectric structure 113. The protective intermediate dielectric 1142 may prevent diffusion and contamination and may protect the ohmic contact 108, e.g. from ALD chemistry.

Referring to the schematic cross-sectional view of FIG. 6D, a trench gate portion on the first surface 1061 is exposed by forming an opening 1145 in the intermediate dielectric structure 113. A gate trench 110 is formed in the SiC semiconductor body 106, e.g. by an etch process.

Referring to the schematic cross-sectional view of FIG. 6E, a gate dielectric 1101 is formed at least on the bottom side and the sidewalls of the gate trench 110, e.g. by high-k layer deposition technique(s). A gate electrode 1102 is formed on the gate dielectric 1101 and recessed up to a top side of the intermediate dielectric structure 113 or up to a top side of the gate dielectric layer 1101 deposited on the intermediate dielectric structure 113.

Referring to the schematic cross-sectional view of FIG. 6F, a second intermediate dielectric layer 1143 as part of the dielectric structure 113 is formed over the protective intermediate dielectric layer 1142. A contact opening is formed, e.g. by a masked etched process, in the intermediate dielectric structure 113 for exposing the ohmic contact 108. The contact opening is filled with a contact plug extending into a first wiring level 1161, e.g. a metal layer closest to the first surface 1061, of a wiring area 116 over the SiC semiconductor body 106.

Similar to the process features described with reference to FIGS. 4A to 4C, omission of the intermediate dielectric layer 114 may also be applied to the exemplary process features of FIGS. 6A to 6F. In addition, the sacrificial layer 118 may also be removed before forming the ohmic contact 108.

The schematic cross-sectional views FIGS. 7A to 7F are for illustrating process features of an exemplary method of manufacturing a semiconductor device 100. The semiconductor device is exemplified as a FinFET.

Referring to the schematic cross-sectional view of FIG. 7A, doped regions are formed in a SiC semiconductor body 106 including an n⁻-doped drift region 1065. The doped regions include an n⁺-doped source region 1011and a p-doped body region 1021. A gate trench 110 is formed in the SiC semiconductor body 106 at a first surface 1061 of the SiC semiconductor body 106. A sacrificial layer 118, e.g. a sacrificial oxide layer, is formed on the first surface 1061 of the SiC semiconductor body 106 and on sidewalls and a bottom side of the gate trench 110.

Referring to the schematic cross-sectional view of FIG. 7B, the gate trench 110 is filled with an auxiliary material 112. An intermediate dielectric layer 114 as part of an intermediate dielectric structure 113 is formed on the surface 1061 of the SiC semiconductor body 106 and patterned by a mask 115, e.g. a resist mask, for defining a contact opening to the first surface 1061 of the SiC semiconductor body 106.

Referring to the schematic cross-sectional view of FIG. 7C, an ohmic contact 108 is formed on the portion of the first surface 1061 of the SiC semiconductor body that is exposed by the contact opening, e.g. by silicidation process. The ohmic contact 108 is covered by a protective intermediate dielectric layer 1142 as part of the intermediate dielectric 113. The protective intermediate dielectric layer 1142 may prevent diffusion and contamination and may protect the ohmic contact 108, e.g. from ALD chemistry.

Referring to the schematic cross-sectional view of FIG. 7D, a top surface portion of the auxiliary material is exposed by forming an opening 1145 in the intermediate dielectric structure 113. The auxiliary material 112 is removed from the gate trench 110, e.g. by an etch process.

Referring to the schematic cross-sectional view of FIG. 7E, the sacrificial layer 118 is removed from the gate trench 110, e.g. by an etch process. A gate dielectric 1101 is formed at least on the bottom side and the sidewalls of the gate trench 110, e.g. by high-k layer deposition technique(s). A gate electrode 1102 is formed on the gate dielectric 1101 and recessed up to a top side of the intermediate dielectric structure 113 or up to a top side of the gate dielectric layer deposited on the intermediate dielectric structure 113.

Referring to the schematic cross-sectional view of FIG. 7F, a second intermediate dielectric layer 1143 as part of the dielectric structure 113 is formed over the SiC semiconductor body 106. A contact opening is formed, e.g. by a masked etched process, in the intermediate dielectric structure 113 for exposing the ohmic contact 108. The contact opening is filled with a contact plug extending into a first wiring level 1161, e.g. a metal layer closest to the first surface 1061, of a wiring area 116 over the SiC semiconductor body 106.

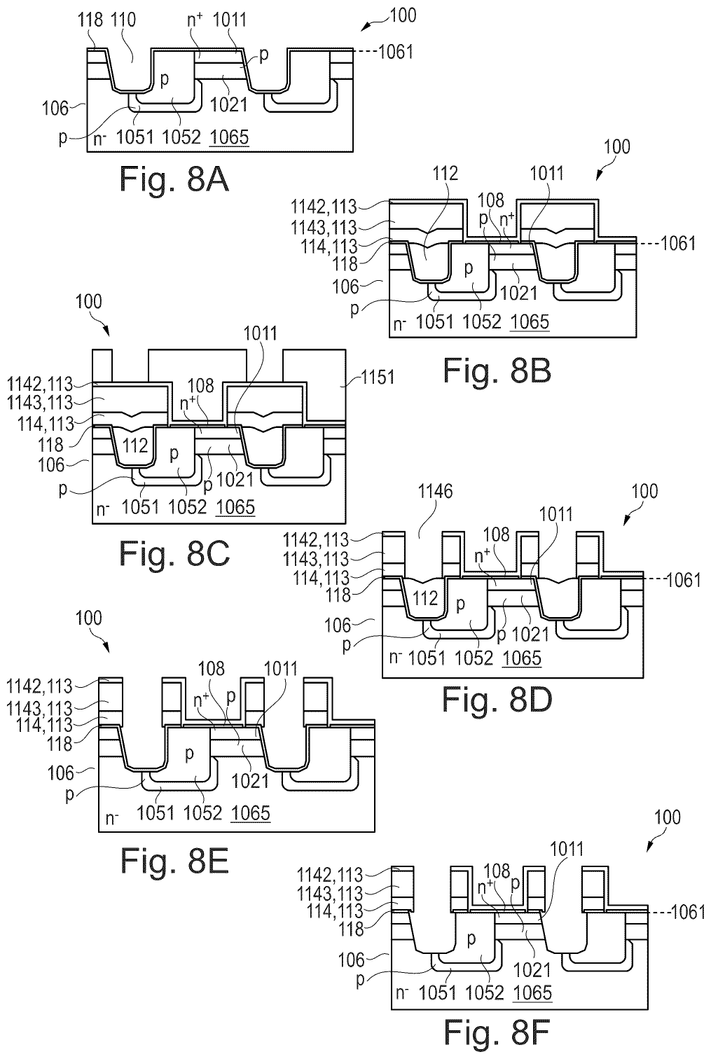

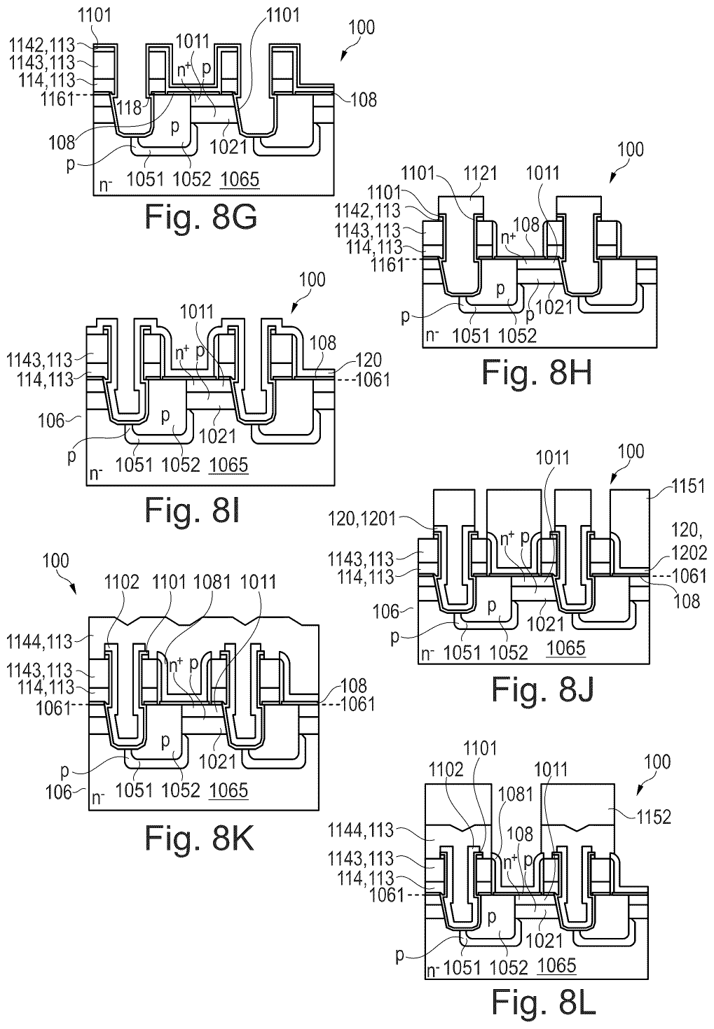

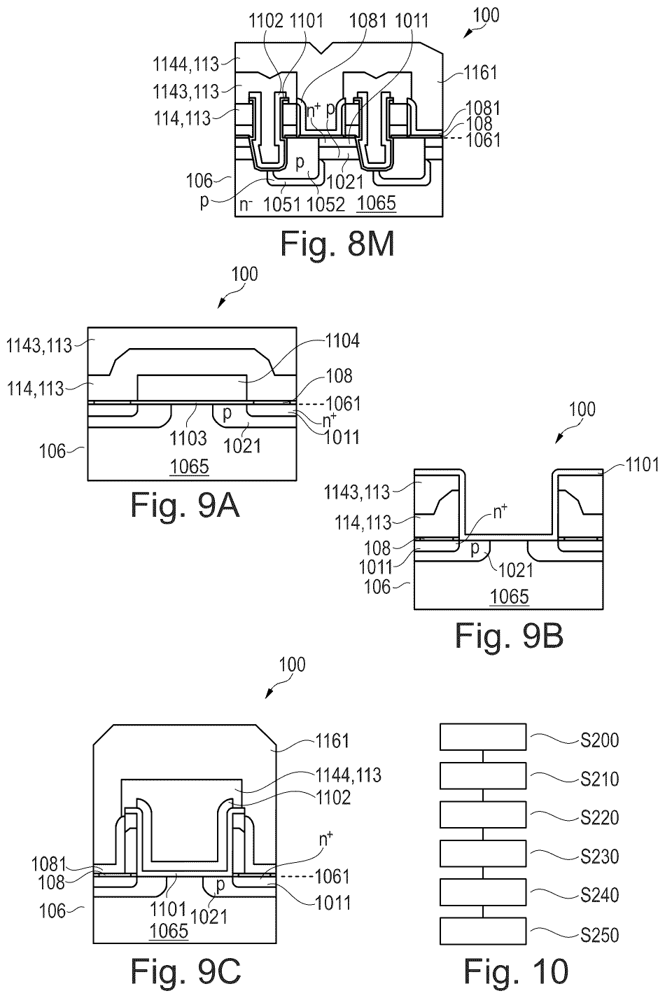

The schematic cross-sectional views FIGS. 8A to 8M are for illustrating process features of an exemplary method of manufacturing a semiconductor device 100. The semiconductor device is exemplified as a trench MOSFET.

Referring to the schematic cross-sectional view of FIG. 8A, doped regions are formed in a SiC semiconductor body 106 including an n⁻-doped drift region 1065. The doped regions include an n⁺-doped source region 1011 and a p-doped body region 1021, a p-doped bottom auxiliary region 1051 and a p-doped top auxiliary region 1052 A gate trench 110 is formed in the SiC semiconductor body 106 at a first surface 1061 of the SiC semiconductor body 106. A sacrificial layer 118, e.g. a sacrificial oxide layer, is formed on the first surface 1061 of the SiC semiconductor body 106 and on sidewalls and a bottom side of the gate trench 110.

Referring to the schematic cross-sectional view of FIG. 8B, the gate trench 110 is filled with an auxiliary material 112, e.g. polycrystalline silicon. An intermediate dielectric layer 114 and a second intermediate dielectric layer 1143 as part of an intermediate dielectric structure 113 are formed on the surface 1061 of the SiC semiconductor body 106 and patterned by a mask, e.g. a resist mask, for defining a contact opening to the first surface 1061 of the SiC semiconductor body 106. An ohmic contact 108 is formed on the portion of the first surface 1061 of the SiC semiconductor body that is exposed by the contact opening, e.g. by a silicidation process. The ohmic contact 108 is covered by a protective intermediate dielectric layer 1142 as part of the intermediate dielectric 113.

Referring to the schematic cross-sectional view of FIG. 8C, a mask 1151 is formed over the intermediate dielectric structure 113 including an opening directly over the gate trench 110.

Referring to the schematic cross-sectional view of FIG. 8D, a top surface portion of the auxiliary material 112 is exposed by forming an opening 1146 in the intermediate dielectric structure 113.

Referring to the schematic cross-sectional view of FIG. 8E, the auxiliary material 112 is removed from the gate trench 110, e.g. by an etch process.

Referring to the schematic cross-sectional view of FIG. 8F, the sacrificial layer 118 is removed from the gate trench 110, e.g. by an etch process.

Referring to the schematic cross-sectional view of FIG. 8G, a gate dielectric 1101 is formed on the bottom side, on the sidewalls of the gate trench 110, and on the protective intermediate dielectric layer 1142, e.g. by high-k layer deposition technique(s).

Referring to the schematic cross-sectional view of FIG. 8H, a sacrificial layer 1121, e.g. a resist structure defined by lithography, is formed on the gate dielectric 1101. A contact opening is formed, e.g. by a masked etched process, in the sacrificial layer 1121, the gate dielectric 1101, and the protective intermediate dielectric layer 1142 for exposing the ohmic contact 108.

Referring to the schematic cross-sectional view of FIG. 8I, the sacrificial layer 1121 is removed and a conductive liner 120, e.g. a Ti/TiN liner is formed inside and outside of the gate trench 110.

Referring to the schematic cross-sectional view of FIG. 8J, the conductive liner 120 is patterned by an etch process using an etch mask 1151. The patterned conductive layer 120 remains as the gate electrode 1102 in the gate trench 110 and as a contact liner 1081 on the ohmic contact 108 that is electrically separated from the gate electrode 1102.

Referring to the schematic cross-sectional view of FIG. 8K, a third intermediate dielectric layer 1144 as part of an intermediate dielectric structure 113 is formed over the SiC semiconductor body 106 and fills up the gate trench 110.

Referring to the schematic cross-sectional view of FIG. 8L, a contact opening is formed, e.g. by a masked etched process, in the third intermediate dielectric layer 1144 for exposing the contact liner 1081.

Referring to the schematic cross-sectional view of FIG. 8M, the contact opening is filled with a contact plug extending into a first wiring level 1161, e.g. a metal layer closest to the first surface 1061, of a wiring area 116 over the SiC semiconductor body 106.

The schematic cross-sectional views of FIGS. 8A to 8M illustrating process features of an exemplary method of manufacturing a trench MOSFET may also be applied for manufacturing a planer MOSFET as illustrated in the schematic cross-sectional views of FIGS. 9A to 9C.

Referring to FIG. 9A, a planar MOSFET including a sacrificial gate dielectric 1103 and a sacrificial gate electrode 1104 may be formed by process features including a sacrificial gate oxide and an ohmic contact 108 that is formed after the sacrificial gate oxide, for example.

Referring to FIG. 9B, a planar gate portion on the first surface 1061 is exposed by forming an opening in the intermediate dielectric structure 113, e.g. by an etch process. The sacrificial gate electrode 1104 is removed, and the sacrificial gate dielectric 1103 is removed and replaced by the gate dielectric 1102, e.g. a high-k dielectric. The process features described with reference to FIGS. 8H to 8M may likewise be applied. This results in the planar MOSFET as illustrated in FIG. 9C

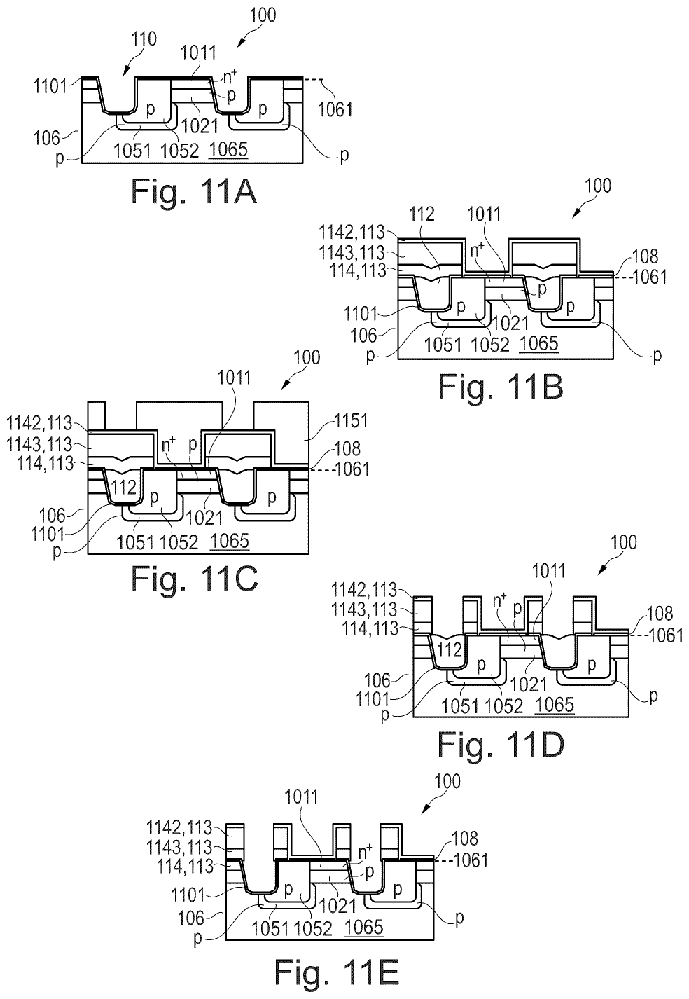

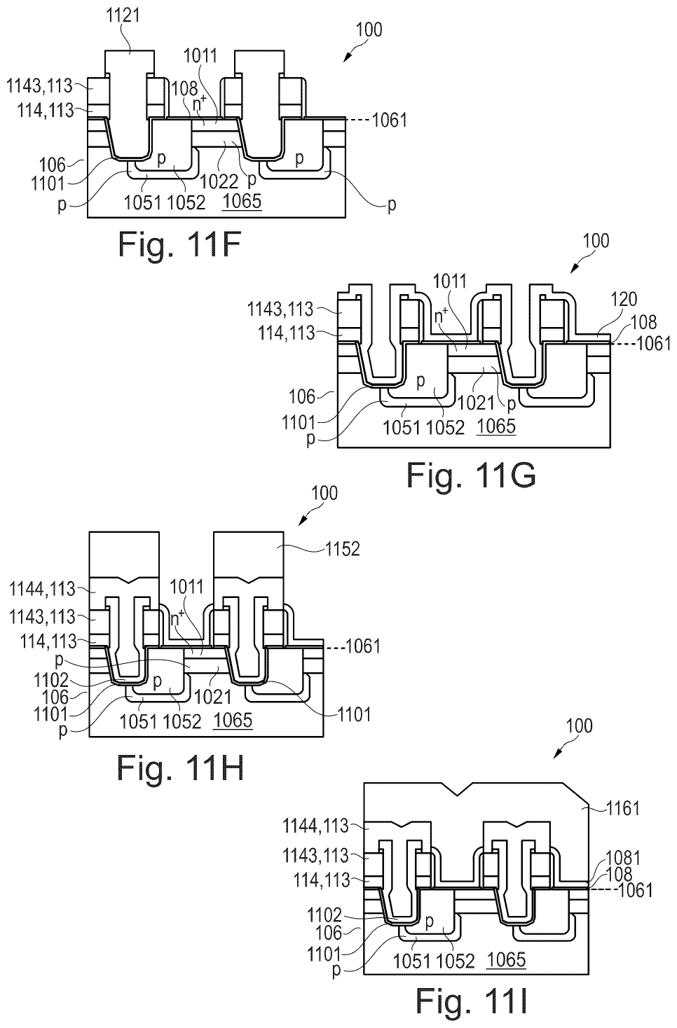

Another example of a method of manufacturing a semiconductor device is illustrated by referring to the flowchart of FIG. 10 and further exemplified in the cross-sectional views of FIGS. 11A to 111.

Process feature S200 includes forming doped regions in a SiC semiconductor body at a first surface of the SiC semiconductor body (see e.g. FIG. 11A).

Process feature S210 includes forming a gate trench into the SiC semiconductor body at the first surface (see e.g. FIG. 11A).

Process feature S220 includes forming a gate dielectric, e.g. an oxide of silicon such as SiO₂, in the gate trench and filling the gate trench with an auxiliary material (see e.g. FIG. 11A).

Process feature S230 includes forming an ohmic contact to at least part of the doped regions on the first surface of the SiC semiconductor body (see e.g. FIG. 11B).

Thereafter, process feature S240 and S250 are carried out.

Process feature S240 includes removing the auxiliary material from the gate trench (see e.g. FIGS. 11C to 11E).

Process feature S250 includes forming a metal layer structure. A first part of the metal layer structure may be formed on the gate dielectric and constitutes a gate electrode. A second part of the metal layer structure may be formed on the ohmic contact (see e.g. FIG. 11F to 111).

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the disclosed subject matter. This application is intended to cover any adaptations or variations of the specific embodiments discussed herein. Therefore, it is intended that the disclosed subject matter be limited only by the claims and the equivalents thereof.

1. A method of manufacturing a semiconductor device, the method comprising:
forming doped regions in a silicon carbide (SiC) semiconductor body at a first surface of the SiC semiconductor body;
forming an ohmic contact to at least part of the doped regions on the first surface of the SiC semiconductor body; and
after forming the ohmic contact, forming a gate dielectric on the SiC semiconductor body.

2. The method of claim 1, wherein forming the ohmic contact comprises processing the SiC semiconductor body at temperatures higher than a crystallization temperature of the gate dielectric.

3. The method of claim 1, further comprising:
before forming the ohmic contact, forming a gate trench into the SiC semiconductor body at the first surface.

4. The method of claim 3, wherein forming the doped regions comprises:
forming a source layer of a first conductivity type;
forming a body layer of a second conductivity type; and
patterning the source layer to source regions and patterning the body layer to body regions by etching through the source layer and etching through the body layer when forming the gate trench, the source regions and the body regions constituting at least part of the doped regions.

5. The method of claim 3, further comprising:
filling the gate trench with an auxiliary material before forming the ohmic contact; and
removing the auxiliary material from the gate trench after forming the ohmic contact and before forming the gate dielectric.

6. The method of claim 5, further comprising:
before removing the auxiliary material, forming an intermediate dielectric layer over the auxiliary material and the first surface of the SiC semiconductor body; and
exposing a top surface portion of the auxiliary material by forming an opening in the intermediate dielectric layer, wherein the intermediate dielectric layer at least one of remains as part of a wiring area over the first surface of the SiC semiconductor body or is replaced by another intermediate dielectric layer.

7. The method of claim 1, further comprising:
before forming the gate dielectric, forming an intermediate dielectric layer on the first surface of the SiC semiconductor body; and
exposing a gate portion of the SiC semiconductor body at the first surface of the SiC semiconductor body, wherein exposing the gate portion of the SiC semiconductor body at the first surface comprises:
forming an opening in the intermediate dielectric layer; and
forming the gate dielectric on the exposed gate portion of the SiC semiconductor body at the first surface of the SiC semiconductor body, wherein the intermediate dielectric layer at least one of remains as part of a wiring area over the first surface of the SiC semiconductor body or is replaced by another intermediate dielectric layer.

8. The method of claim 7, further comprising:
after forming the intermediate dielectric layer and before exposing the gate portion, exposing a contact portion of the SiC semiconductor body at the first surface of the SiC semiconductor body, wherein exposing the contact portion of the SiC semiconductor body at the first surface comprises:
forming an opening in the intermediate dielectric layer; and
forming the ohmic contact on the exposed contact portion of the SiC semiconductor body at the first surface of the SiC semiconductor body.

9. The method of claim 7, further comprising forming a metal layer structure, wherein a first part of the metal layer structure is formed on the gate dielectric and constitutes a gate electrode, and a second part of the metal layer structure is formed on the ohmic contact.

10. The method of claim 1, further comprising:
after forming the ohmic contact, forming a gate trench into the SiC semiconductor body at the first surface.

11. The method of claim 10, wherein forming the doped regions comprises:
forming a source layer of a first conductivity type;
forming a body layer of a second conductivity type; and
patterning the source layer to source regions and patterning the body layer to body regions by etching through the source layer and etching through the body layer when forming the gate trench, the source regions and the body regions constituting at least part of the doped regions.

12. The method of claim 10, further comprising:
before forming the gate trench, forming an intermediate dielectric layer on the first surface of the SiC semiconductor body; and
exposing a gate portion of the SiC semiconductor body at the first surface of the SiC semiconductor body, wherein exposing the gate portion of the SiC semiconductor body at the first surface comprises:
forming an opening in the intermediate dielectric layer; and
forming the gate trench into the SiC semiconductor body at the first surface, wherein the intermediate dielectric layer at least one of remains as part of a wiring area over the first surface of the SiC semiconductor body or is replaced by another intermediate dielectric layer.

13. The method of claim 12, wherein the intermediate dielectric layer is formed before forming the ohmic contact, the method further comprising:
exposing a contact portion of the SiC semiconductor body at the first surface of the SiC semiconductor body, wherein exposing the contact portion of the SiC semiconductor body at the first surface comprises:
forming an opening in the intermediate dielectric layer; and
forming the ohmic contact on the exposed contact portion of the SiC semiconductor body at the first surface of the SiC semiconductor body.

14. The method of claim 1, wherein:
forming the doped regions comprises:
forming a source layer of a first conductivity type;
forming a body layer of a second conductivity type; and
patterning the source layer to source regions and patterning the body layer to body regions by etching through the source layer and etching through the body layer when forming gate trenches, the source regions and the body regions constituting at least part of the doped regions;
filling the gate trenches with an auxiliary material before forming the ohmic contact; and
removing the auxiliary material from the gate trenches after forming the ohmic contact and before forming the gate dielectric.

15. The method of claim 14, further comprising:
before forming the ohmic contact, forming an intermediate dielectric layer over the auxiliary material and the first surface of the SiC semiconductor body; and
exposing a contact portion of the SiC semiconductor body at the first surface of the SiC semiconductor body, wherein exposing the contact portion of the SiC semiconductor body at the first surface comprises:
forming an opening in the intermediate dielectric layer; and
forming the ohmic contact on the exposed contact portion of the SiC semiconductor body at the first surface of the SiC semiconductor body.

16. The method of claim 15, further comprising:
before removing the auxiliary material, exposing a top surface portion of the auxiliary material by forming an opening in the intermediate dielectric layer, wherein the intermediate dielectric layer remains as part of a wiring area over the first surface of the SiC semiconductor body; and
forming the gate dielectric.

17. The method of claim 16, wherein the semiconductor device is a fin field effect transistor (FinFET).

18. The method of claim 1, wherein forming the gate dielectric comprises forming a high-k dielectric.

19. A method of manufacturing a semiconductor device, the method comprising:
forming doped regions in a silicon carbide (SiC) semiconductor body at a first surface of the SiC semiconductor body;
forming a gate trench into the SiC semiconductor body at the first surface;
forming a gate dielectric in the gate trench;
filling the gate trench with an auxiliary material;
forming an ohmic contact to at least part of the doped regions on the first surface of the SiC semiconductor body;
removing the auxiliary material from the gate trench; and
forming a metal layer structure, wherein a first part of the metal layer structure is formed on the gate dielectric and constitutes a gate electrode, and a second part of the metal layer structure is formed on the ohmic contact.

20. A method of manufacturing a semiconductor device, the method comprising:
forming one or more doped regions in a silicon carbide (SIC) semiconductor body at a first surface of the SiC semiconductor body;
forming a gate trench into the SiC semiconductor body at the first surface;
forming a gate dielectric in the gate trench;
forming an ohmic contact to at least part of the one or more doped regions on the first surface of the SiC semiconductor body;
removing auxiliary material from the gate trench;
forming a first part of a metal layer structure on the gate dielectric; and
forming a second part of the metal layer structure on the ohmic contact.
